(19) United States
(12) Patent Application Publication
(10) Pub. No.: US 2012/0216465 A1
(43) Pub. Date: Aug. 30, 2012

(54) Fastener free assembly system for solar panel arrays

(76) Inventor: Peter Vari, Richboro, PA (US)

(21) Appl. No.: 12/657,322

(22) Filed: Jan. 19, 2010

(51) Int. Cl. E04D 13/18; F24J 2/52; H01L 31/18

(52) U.S. Cl. 52/173.3; 29/890.033; 248/220.21

(57) ABSTRACT

A mounting system for attaching solar panels or similar structures to a surface and to each other to form an array is disclosed. In accordance with the invention, a bracket that has an upper section with a mounting surface and a retaining lip spaced apart to accept an edge of the panel is provided. A riser connects the upper section to a base disposed on the surface. A ballast disposed against the base keeps the array in place. When the edges of the panels are engaged under the retaining lip of each bracket and the brackets moved to lock the panel in place, the array remains mounted to the surface without mechanical fastening. In certain embodiments, a wind deflector is attached between adjacent panels, and in certain embodiments a separator block is also inserted to fully lock the panels in place. Methods of assembling an array of panels without tools or fasteners are also disclosed.

The present invention is directed to systems, devices for use with systems, and methods of mounting and retaining solar panels on a surface such as a roof, and in particular a flat roof.

### BACKGROUND OF THE INVENTION

Solar panels are typically purchased from manufacturers in the form of individual panels. To generate electricity a single panel, or a group of solar panels called an array, are mounted in an area exposed to the sun. An array can be mounted on a rooftop or on the ground, and to optimize the amount of sunlight striking the panels, they are angled from the horizontal. The angle is chosen based on latitude and other factors according to formulae well known in the art. Because arrays are installed outdoors, they are exposed to wind and weather. They are also subject to interference from humans and sometimes wildlife. It is therefore important that solar panels be mounted securely. Therefore, there are numerous prior art systems that purport to provide structures to mount solar arrays to surfaces.

Numerous systems exist in the prior art for building and securing arrays of solar panels. For example, U.S. Patent Application Publication No. 20090242014 discloses a system for mounting and retaining solar panels with an attachment mechanically coupled to a link member, which is embedded in a ballast. U.S. Pat. No. 7,600,349 discloses a mounting system that has a number of tracks formed in a rail with opposing jaws that define a slot. The opposing jaws are asymmetrical to the longitudinal axis of the rail. A coupler connects the solar panel to the rail. A cleat also is provided for attaching the system to the roof, and a connector connects the rail to the cleat. U.S. Pat. Nos. 7,434,362 and 7,260,918 disclose variations on a system for mounting a device on a surface using one or more dual track rails that includes a clamp configurable in two different configurations for securing the rails to a footing grid. U.S. Pat. No. 7,481,211 discloses a system for mounting solar panels using a base, a solar panel receiving structure, and a support structure coupling the base to the solar panel receiving structure. The first side member and the second side member are slotted so as to slidably receive at least one solar panel between the first side member, the second side member, and the base member. U.S. Patent Application Publication No. 20080310913 discloses a fixture for attaching a profile rail having an undercut longitudinal groove to another component. U.S. Pat. No. 6,968,654 discloses a mounting structure for a solar panel unit that has a frame formed by sheet metal bending operations.

In general, however, all prior art systems rely on one or more of mechanical fasteners between the panels and the support structures, fasteners between elements of the support structures themselves and even mechanical connections that penetrate or otherwise require modification to a roof or associate structures. For one example, U.S. Pat. No. 7,406,800 discloses a frame and racking system for a solar panel. This patent is representative of the prior art in that the design relies heavily on bolts, screws and other fasteners. Similarly, U.S. Patent Application Publication No. 20060118163 discloses a rack assembly for mounting solar panels and is another example of a typical prior art system held together by bolts.

However, in general, it is less than desirable to assemble solar arrays using individual mechanical fasteners. Such systems are time consuming to assemble and require tools and skill. A fastener is easily lost and presents a hazard, particularly in rooftop installations, where they might be dropped and where requiring assembly personnel to reach awkwardly is also a danger. Finally, it is not typically a good idea to puncture the roof, while in ground installations it is desirable to not have to sink footings or create slabs. Thus there exists a long felt and as of yet unmet need for a system by which a series of solar panels can be locked together easily, without fasteners and the associated tooling. It would further be desirable to provide a system has a minimum number of components and that can be assembled on the roof or other surface, rather than requiring unwieldy subassemblies to be constructed and carried into place. Another important feature is for an assembly system to be modular and not need to be customized for various sizes of panels, yet provide more support than just the corners of the panel frame. Finally, it would also be desirable to provide a solar panel assembly system that can be securely mounted to the roof or other surface in a simple manner that leaves the surface intact.

### SUMMARY OF THE INVENTION

The deficiencies of the prior art are overcome by the present invention, which in preferred embodiments provides a mounting system for attaching a panel to a surface that has a bracket with an upper section that has a mounting surface and a retaining lip spaced apart to accept an edge of the panel. A riser is connected to the upper section, and a base connected to the riser is disposed on the surface. The system also preferably includes ballast disposed against the base. When assembled, the edge of the panel is locked in place and remains mounted to the surface without mechanical fastening. In certain embodiments, the bracket has a second upper section having a second mounting surface and a second retaining lip spaced apart to accept an edge of a second panel, which may either be connected to a common base by a single riser or by a first riser and a second riser. In certain embodiments, the first riser is of a first height and the second riser is of a second height, and as a result the panel will be mounted at an angle to the surface. In preferred embodiments, a grounding clip is placed between the bracket and the panel. When installed in arrays of multiple panels, two brackets are attached to a first edge of a first panel and a third and fourth bracket are attached to an opposing second edge of the same panel. In turn, the third and fourth brackets are attached to an first edge of a second panel, and thus a bracket will span the gap between sets of panels and in certain preferred embodiments, an air deflector covers the gap between the panels. In a preferred embodiment, the array is an array of solar panels mounted to a roof, using a plurality of brackets so that the edges of the panels are locked in place and remain mounted to the surface without mechanical fastening. In certain embodiments a grounding lug is located on the side of the riser 106 to facilitate wiring and thus grounding the brackets together if necessary. Also, in certain embodiments a support bracket is located on the side of the riser 106 to facilitate supporting electrical conduits for wire runs.

The present invention also provides methods of installing an array of solar panels on a surface without using fasteners. In accordance with this aspect of the present invention a pair of brackets is placed on the surface and an edge of a first panel is slid between a mounting surface and a retaining lip disposed on the brackets. Ballast is placed on the brackets and then a second edge of the panel is slid between a second mounting surface and a second retaining lip disposed on a second set of brackets. The two sets of brackets are then pulled away from one another and the process is repeated to build out an array, with air deflectors installed to cover any gaps between panels.

### BRIEF DESCRIPTION OF DRAWINGS

FIG. 1 is a perspective view of a set of solar panels mounted to a roof in accordance with the present invention;

FIG. 2 is a perspective view of a single solar panel mounted to a pair of mounting brackets made in accordance with the present invention;

FIG. 3 is a perspective view of an edge of a solar panel and the mounting point that forms part of one of the mounting brackets illustrated in FIG. 2;

FIG. 4 is a perspective view of a mounting bracket made in accordance with the present invention;

FIG. 5 is a perspective view of the mounting bracket shown in FIG. 5 with ballast blocks in place;

FIG. 6 is a perspective view of a pair of another embodiment of mounting brackets made in accordance with the present invention;

FIG. 7 is a side elevation view of an array of solar panels connected using the brackets shown in FIG. 6;

FIG. 8 is a more detailed view of the array of solar panels illustrated in FIG. 7;

FIG. 9 is an illustration of a grounding clip disposed between a bracket and a solar panel; and

FIG. 10 is a perspective view of a separator block being placed between two adjacent panels.

### DETAILED DESCRIPTION OF THE PREFERRED EMBODIMENTS

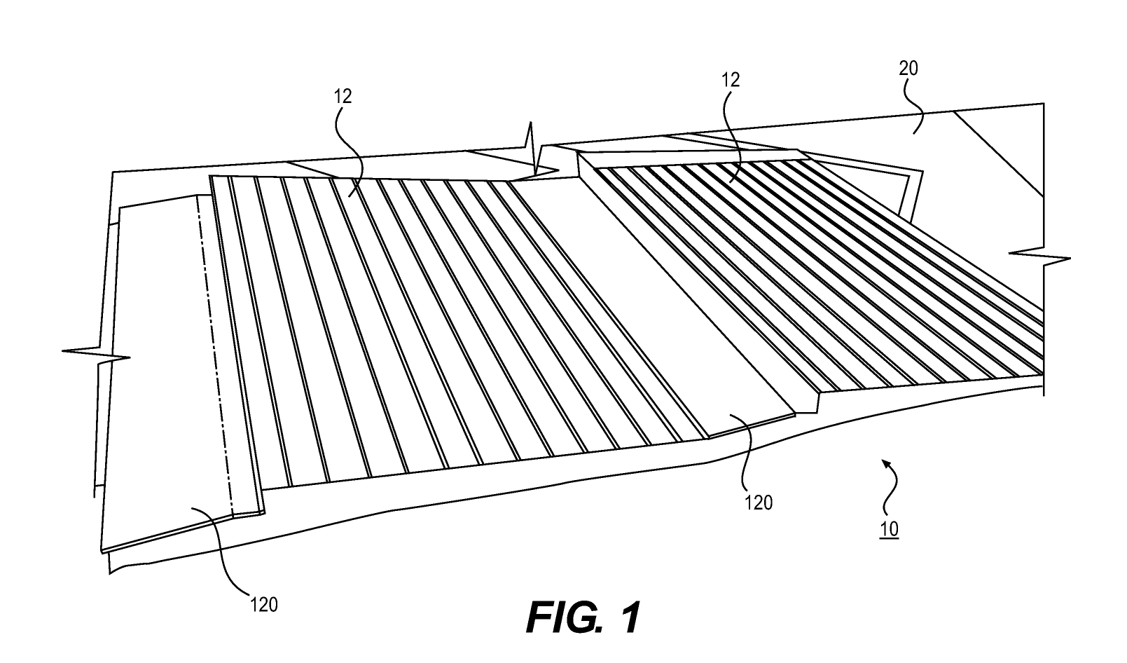

Referring now to FIG. 1, there is illustrated a typical section of an array 10 of solar panels 12. The panels 12 are usually part of a large array typically installed on a flat roof of a commercial building. It will be understood that the present invention is not limited to flat roof installations, or to commercial installations, but is widely applicable to various roof structures and other mounting surfaces, including being mounted on the ground. Numerous manufacturers supply the panels 12 in a variety of sizes and with different physical dimensions, such as the shape and thickness of the edges. The edges are usually within a known dimensional range and usually comprise an extruded aluminum frame that provides a measure structural support and rigidity to each panel such that the entire perimeter does not need to be supported.

The array 10 illustrated in FIG. 1 will be made of a plurality of solar panels 12, although only two solar panels 12 are shown in FIG. 1 and those skilled in the art will appreciate that additional rows and columns of individual panels 12 typically create an array 10. As seen in FIG. 1 the panels are typically but not necessarily at an angle mounted relative to the roof or other surface 20 which may itself be at an angle to the horizontal. Those skilled in the art are familiar with the considerations that go into choosing the angle at which each panel or row of panels 12 will be mounted relative to the horizontal. Thus, in some embodiments, each panel 12 of an entire array will be at the same angle, while in others the angle may vary from section to section or even panel to panel. It is further understood that although a certain size and aspect ratio of the panel 12 is illustrated, the present invention is useful with any size and style of solar panel, or any other similar item such as a reflector, illumination array or the like that has structural characteristics and mounting requirements similar to the solar panels shown in the drawings. Finally, as seen in FIG. 1, the array 10 rests on a surface 20 (is 20 shown on the drawing?), which is typically a flat roof but can be any other suitable surface. As explained in detail below, the surface 20 is not punctured to mount the array 10, nor is any mechanical structure extending from the surface 20 necessary for assembling and securing the array 10. As also explained in further detail below, in high-wind installations special fasteners that penetrate the surface 20 or other anchoring might be necessary.

FIG. 1 also illustrates deflector elements 120 that typically are included in an array 10. Because the faces of the solar panels 12 are almost always directed generally in the direction of the sun (e.g., toward the South in the Northern Hemisphere) an accommodation must be made to deflect the wind that would otherwise flow beneath each panel 12 and create lift. In some embodiments, each solar panel has a corresponding deflector element 120, but in certain embodiments certain of the solar panels will not have an accompanying deflector 120 while in other embodiments a deflector may span multiple panels. The deflector 120 can be made of sheet metal, fiberglass, plastic or any other suitable material. Most preferably, the deflector 120 is designed so it attaches to a bracket 100 and/or the solar panel(s) 12 without tools and without the use of separate fasteners, using a sliding and snap fit between the edges of the deflector and the panels 10.

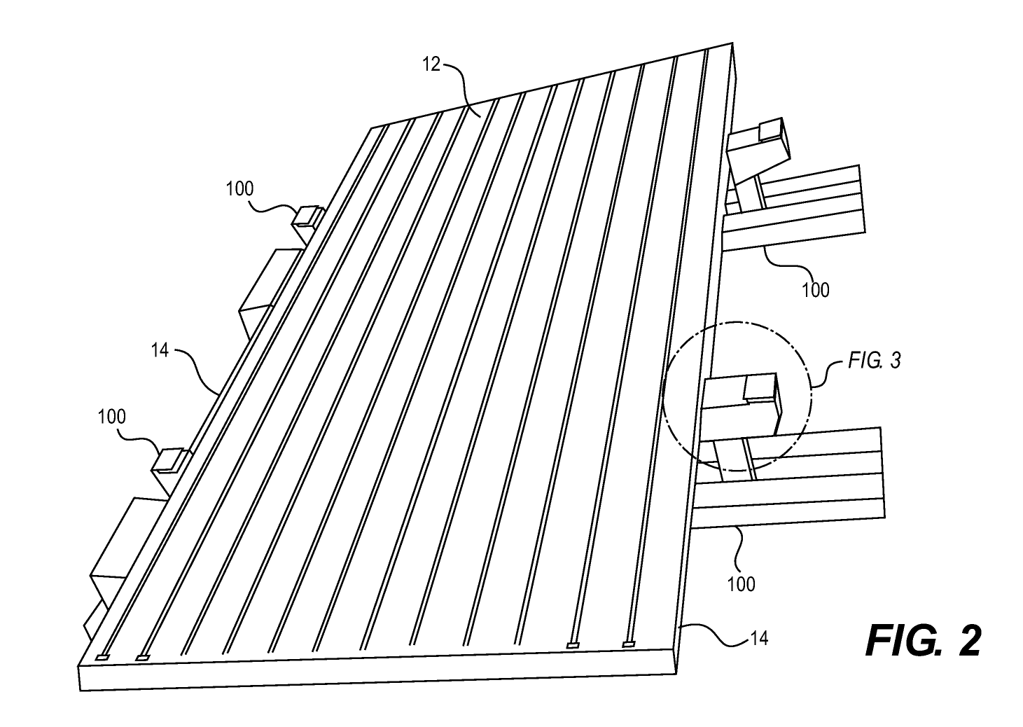

Referring now to FIG. 2, the mounting system of the present invention is described in further detail using a single solar panel 12. As seen in FIG. 2, the panel 12 rests on four brackets 100, only a portion of each being visible in this illustration. Typically, but not necessarily, the brackets 100 support two opposing sides of a panel 12 and the brackets 100 are identical, except in certain cases as noted below. The brackets 100 may be located anywhere along the sides of each panel 12, depending on the rigidity of each panel and the maximum unsupported length that can be tolerated in accordance with manufacturer's specifications and good engineering practice. On the other hand, with certain very heavy or very structurally unsound panels, additional brackets 100 may need to be inserted along each side to support the panel properly. In accordance with the present invention, and as explained in further detail below, the four brackets 100 grip and lock the solar panel 12 by engaging with the edges of the frame 14 that surround the panel 12. The system of the present invention thus does not require bolts, threaded holes, adhesives, soldering, or any other technique to attach each panel 12 to a respective bracket 100.

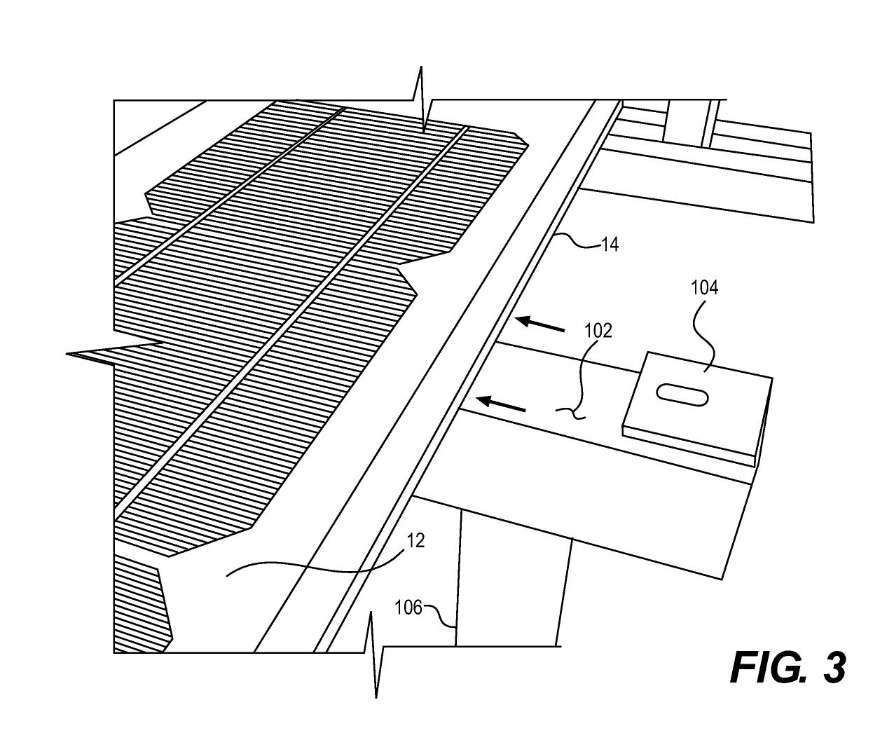

Referring now to FIG. 3, further details of the attachment between a bracket 100 and the frame 14 of a panel 12 seen in FIG. 2 are shown. The bracket 100 preferably includes an upper section that has a mounting surface 102 and a retaining lip 104 that are sufficiently spaced apart to create a slot or recess that accepts the inside edge 14 of the panel 12. A riser 106, described below, supports this structure. In FIG. 3, the solar panel 12 has been installed by sliding it in the direction of the arrows so it is engaged with and covering the retaining lip 104 (not visible) and is locked in place. The visible retaining lip 104 is ready to accept the next panel 12 in an array 10, which will be slid into place in the opposite direction, covering the retaining lip 104 that is visible in FIG. and leaving a small gap between the clean edges of a pair of panels 12. Alternatively, the exposed retaining lip may be left empty or, preferably, is covered in the case of the edge rows of an array.

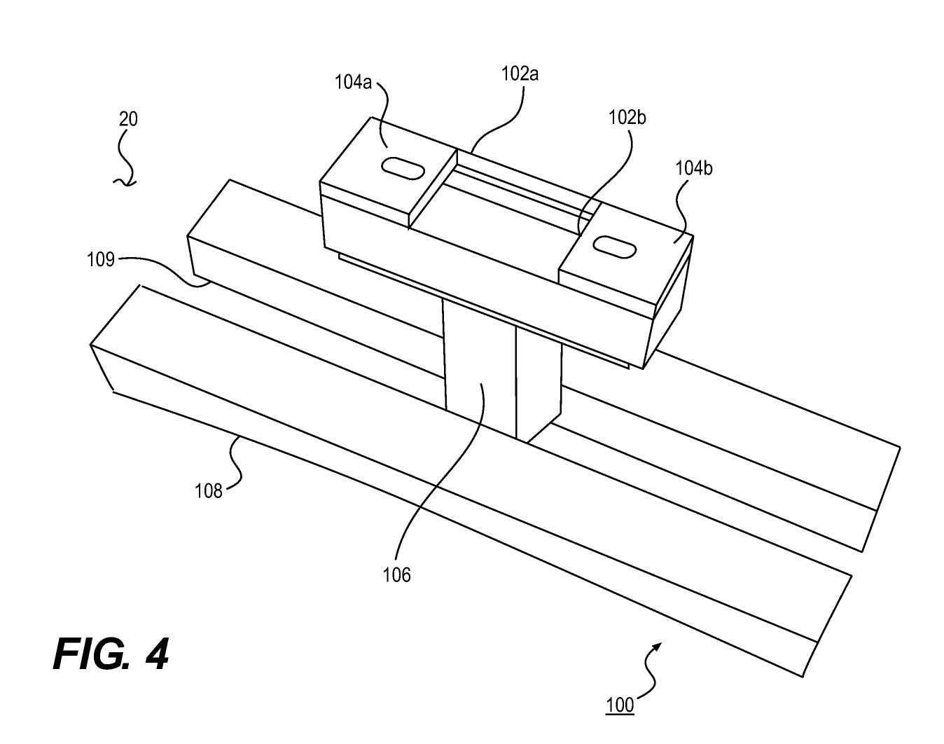

Additional details of the brackets 100 made in accordance with the present invention may be better explained with reference to FIG. 4, which illustrates a perspective view of a single bracket 100 prior to installation. In preferred embodiments the bracket 100 is made of aluminum or a similar metal that is suitable for outdoor installation, although plastics and fiber composite materials may also be useful to create the brackets 100. As described above, each bracket 100 actually spans between and attaches the adjacent edges of two separate panels 12 (not shown in FIG. 4). Each bracket 100 thus includes a first a mounting surface 102a and a first retaining lip 104a, as well as a second mounting surface 102b and a second retaining lip 104b. The bracket 100 has a riser 106 that connects this structure to a base 108. The base 108 in turn rests on the roof or other surface 20. The base 108 is illustrated as being made from two parallel sections of square tubing, however, the base 108 may be comprised of any of a number of structural shapes, e.g., round tubes, triangular extrusions, plate elements or the like. In certain preferred embodiments, the lower surface 109 of the base 108 is either coated with a material or has a layer of material such that is attached, glued to the bottom of the base. The purpose of the material is to make sure that the bracket does not abrade the roof covering. One useful material is a layer of EPDM, although there are numerous other rubber, foam, elastomeric and plastic materials that are suitable.

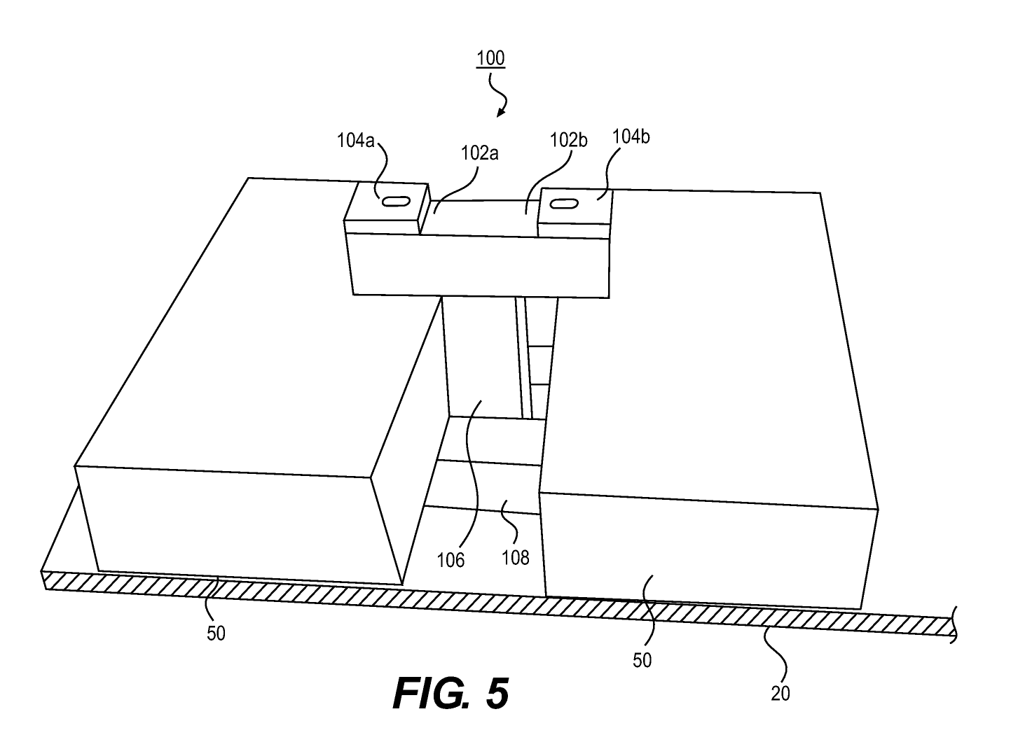

The size and shape of the base 108 may be of any configuration that is sufficient to accept ballast that will secure the array 10 without mechanical fasteners or additional structural elements. FIG. 5 illustrates the placement of ballast 50 to secure bracket 100 to keep it and the entire array 10 in place. Those skilled in the art will readily understand that the base 108 makes contact with the roof or other surface and is designed to accept a the size and weight of the ballast 50, such as a standard paving block, concrete block, brick or the like. Such items are preferred for use as ballast 50 since they are readily available, consistent in terms of size and weight, are weather resistant, and it is easy to install and remove without tools.

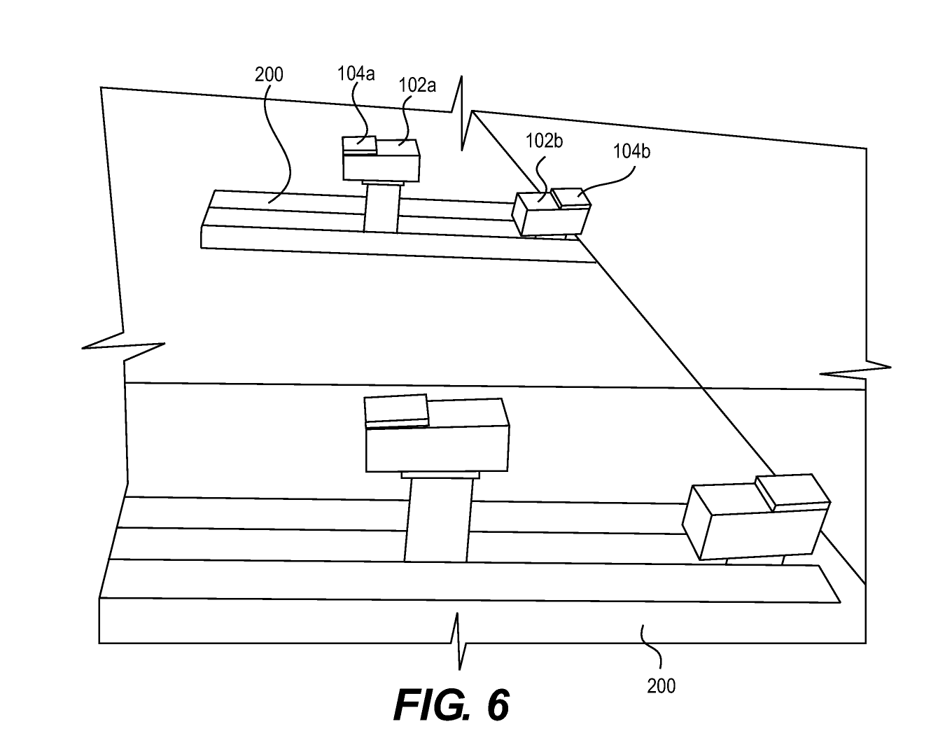

It should be noted that the brackets 100 illustrated in FIGS. 2-5 are designed to create pairs of rows that are at the same height and approximately the same angle. They are typically be used in a situation where the array is located on a larger framework structure either on the ground or on the roof or other surface. However, in another embodiment shown in FIG. 6, the brackets 200 tilt each panel 12 relative to the surface and thus, for example, create an array at the optimal angle of incidence on a flat roof. The resulting array 10 was illustrated and described above with reference to FIG. 1. It will be understood that the structure and method of locking each panel 12 in place is the same in either embodiment of the bracket (100,200).

FIG. 6 illustrates a pair of brackets 200 in position to receive a single solar panel (not shown). As mentioned above with reference to the first design, each bracket 200 preferably includes two upper sections, each of which has mounting surfaces 102a,102b and matching retaining lips 104a,104b. On each bracket 200 there is a first mounting surface 102a and a retaining lip 104a retain the rear edge of a first panel 12 (not shown). while the front edge of this panel is locked in place by a second surfaces 102b and second retaining lips 104b of another pair of brackets 200 that are located to the left. The front edge of the adjacent panel is locked in place by third mounting surfaces 102b and third retaining lips 104b. In the embodiment shown in FIG. 6, the second upper section is affixed to a relatively short riser 106b. The two risers 106a,106b are affixed to base 108. In the embodiment illustrated, the base 108 is a pair of square tubes, in a similar manner to the bracket 100 illustrated in FIGS. 2-5.

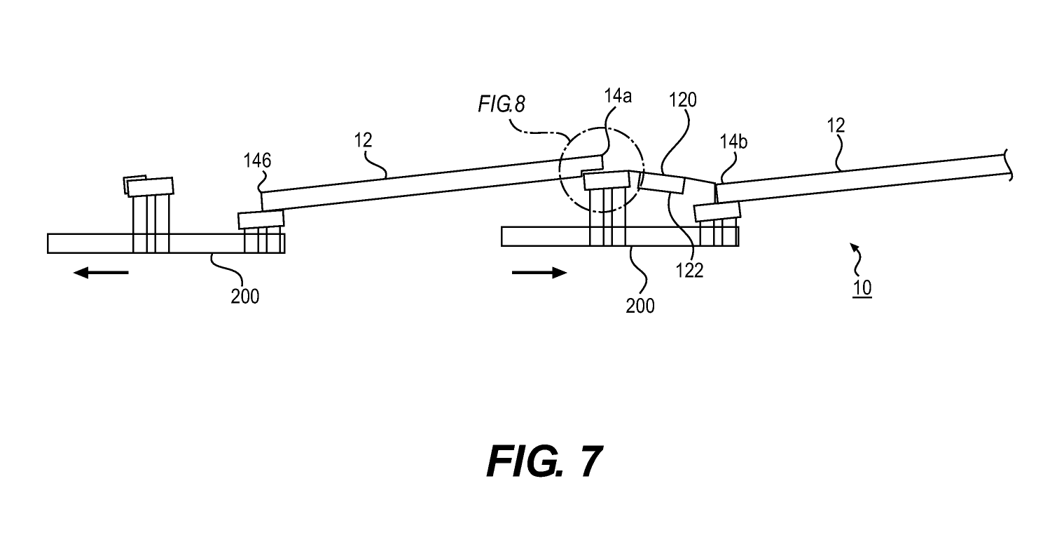

Referring now to FIG. 7, a more schematic elevation view of part of an array 10 of solar panels 12 is shown. In FIG. 7, a side elevation view of two brackets 200 made substantially in accordance with the brackets 200 illustrated with reference to FIG. 6 are shown in place and it can be seen how one bracket 200 retains the rear edge of one panel 14a and the front edge of the adjacent panel 14b. A side view of a sheet metal air deflector 120 is also visible, including a downturned tab 122 that adds rigidity and minimizes vibration. The bracket 200 holding the lower edge of the panel 12 on the left can either accept the rear edge of the next panel in the array 10 (not shown), or can be capped or left as is if the array 10 does not extend further to the left. As the array 10 is constructed, each row is filled out and then the sets of brackets 200 are pulled in the direction of the arrows shown in FIG. 7 to lock the mounting surfaces 102 and the retaining lips 104 to the edges 14 of the panels 12. The result is an assembly similar to that shown in FIG. 1.

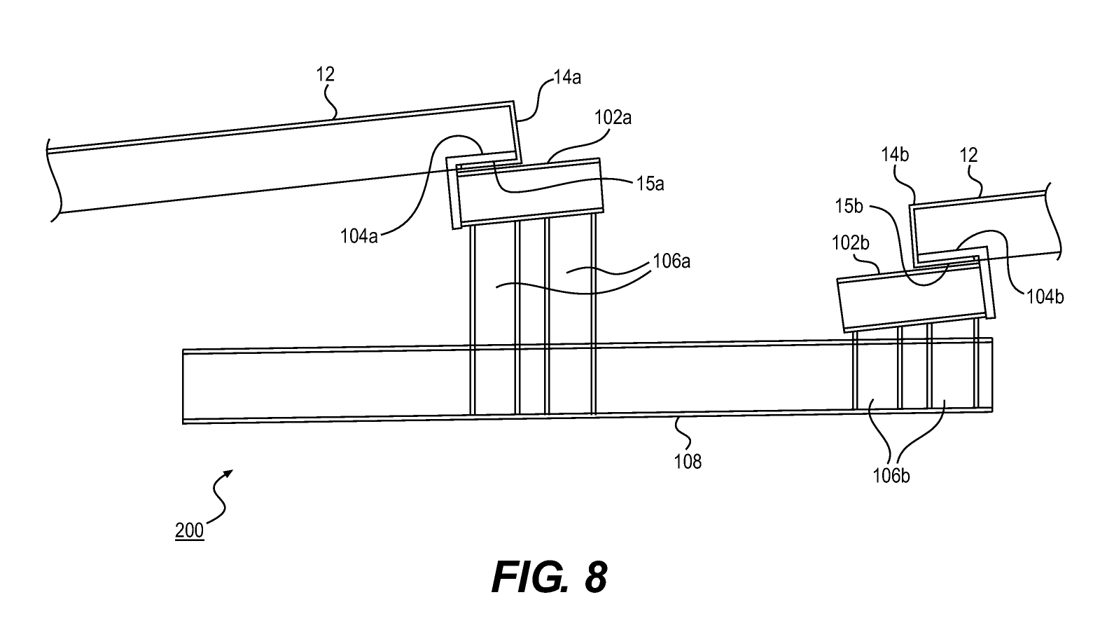

FIG. 8 is an enlarged detail of one of the brackets 200 shown in FIG. 7 and is essentially a side elevation view of one of the brackets 200 seen in FIG. 6 but also illustrates how a pair of panels 12 engages the bracket 200. In this view, the engagement of the panel edges 14a,14b with the bracket 200 is more clearly seen. The lower portion of each edge 15a,15b slides between the respective mounting surfaces 102a,102b and matching retaining lips 104a,104b to be locked in place. It is also more readily appreciated in this view that the mounting surfaces 102a,102b are angled relative to the base 108. In the embodiment illustrated in FIGS. 7-8, the risers 106a,106b are shown as twin upright structural elements, as opposed to the design shown in FIG. 6, which used a single element.

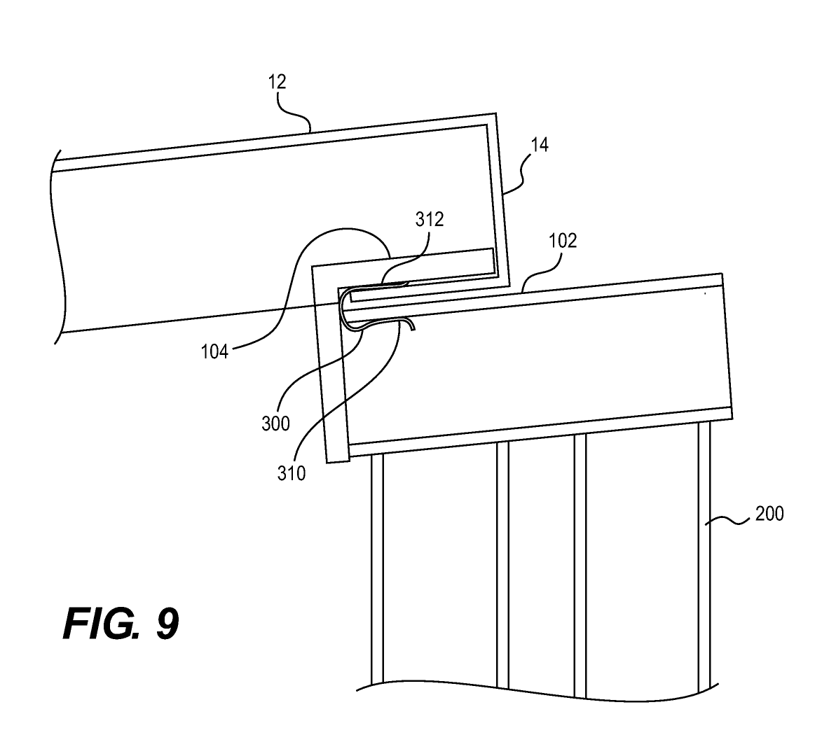

In certain embodiments, it may be desired to ensure grounding of the panels 12 and create a grounding path. The present invention provides a grounding clip 300 to ensure an electrical connection to ground from panel to mounting surface 102, provided that the panels 12 and brackets (100,200) are either made of a conductive material or contain embedded wires or the like to be sufficiently conductive. As seen in FIG. 9, in one preferred embodiment, a conductive grounding clip is inserted into the ends of each mounting surface 102 prior to welding or affixing the elements that form each upper lip 104. In this manner, the arc or bend of the legs of the clip act as weak leaf springs and fill any gap between the bracket structure and the edge 14 of the panel 12. (As seen in FIG. 9, the top of the clip 312 is preferably located on the top side of the solar module frame edge so the barb 310 or other point of contact cuts into the solar panel 12 as well as into the brackets?,200). Most preferably, a barb or point 310 is formed in each leg of the clip 300 to ensure electrical connection and resist oxidation and movement. Numerous variations of both the design of the clip and its location are of course possible and would be as effective as the illustrated embodiment.

The present invention also provides methods of installing an array of panels. In accordance with this aspect of the present invention and with reference to FIG. 7, a pair of brackets 200 is first put in place, and preferably the ballast 50 (not shown in FIG. 7) is added. A panel 12 is then connected at its the lower (left) edge 14b and temporarily supported while a second pair of brackets 200 is slipped under the panel 12 and engaged with the upper (right) edge 14a. Moving each of these two pairs of brackets away from one another as shown by the arrows in FIG. 7 locks the structure together without any fasteners. Ballast 50 is then added to the second set of brackets 200 (on the right in FIG. 7), and the lower (left) edge 14b of a new panel 12 is added and the process repeated. (Said another way, once a first panel is assembled in the above described fashion a new panel is added such that two more brackets (one pair) are added and these new brackets are pulled away from the already assembled panels. Therefore, only the two new brackets need to be pulled to lock in the next panel and the pair already in place remain stationary but provide a counter force. The air deflector 120 is installed to cover the span between the panels. Those skilled in the art will understand that the steps of the method of the present invention can be carried out in any of a number of alternate sequences and that all the steps need not be performed or that additional or alternate steps may be performed.

Although the system of the present invention thus does not require fasteners to assemble a group of panels 12 into an array 10, it will be appreciated that in certain limited situations an attachment point may require a supplemental fastener. For example, on rare occasions where it is otherwise physically impossible to correctly slide a panel in place, or where a partial or cut bracket is needed, or where extreme wind conditions mandate selectively bolting a limited number of brackets to the supporting structure. Such measures required by odd geometry or by safety concerns do not vitiate or materially deviate from the improvements provided by the present invention where panel after panel is slid in place and locked by brackets having the structural elements illustrated and described.

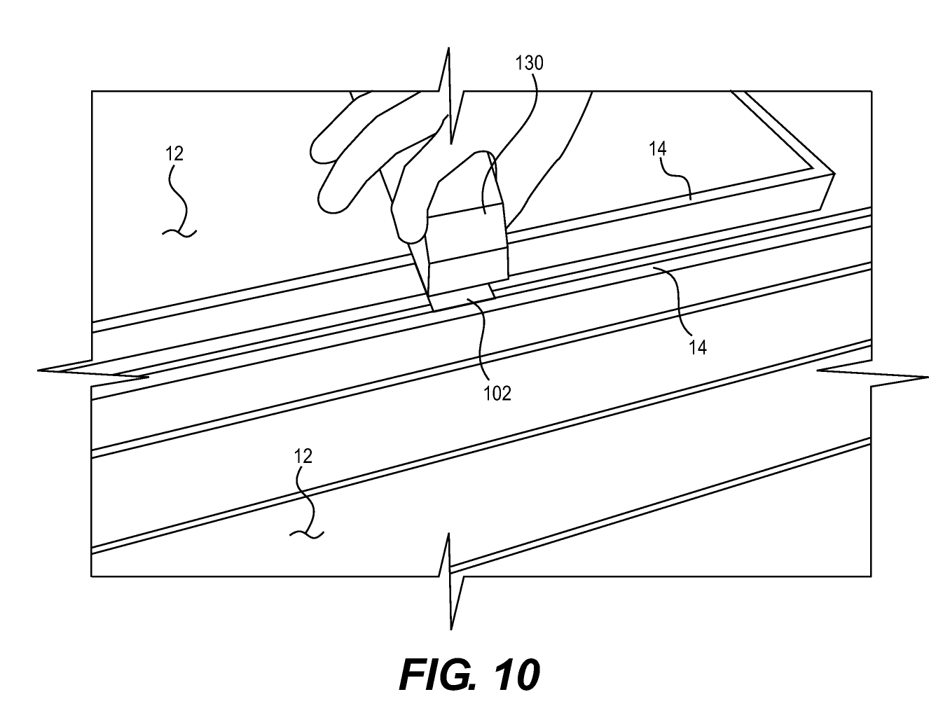

Another aspect of the present invention is illustrated in FIG. 10. As shown, in certain preferred embodiments, a small separator block 130 is used to fully retain the panels 12 relative to one another. Once the two adjacent panels 12 are assembled using brackets as described above, the block 130 is dropped between the panels on top surface 102 of each bracket to ensure that the panels cannot be dislodged by moving the portion of the panel edges 1,4 retained under the brackets. The two panels 12 with the separator block 130 between them form a unit that does not have enough clearance to allow a panel to come free. In other words, the separator block 130 takes away the clearance necessary to assemble the panels to the bracket. Alternatively, a pin or other mechanical element could be used for the same purpose on the angled brackets, thus, as used herein, the term “block” or “separator block” is not limited to a component of the shape or size shown in FIG. 10. In accordance with the aspects of the invention described above, the block 130 remains in place by gravity and friction and does not require fasteners to be held in place, nor does it require tools to be installed or removed.

The embodiments of the present invention are not limited to the details of construction and the arrangement of components set forth in the foregoing description or illustrated in the drawings. The present invention lends itself to numerous other embodiments, and the embodiments illustrated and described herein should not be regarded as limiting. Upon review of the description and drawings, those skilled in the art will readily devise various alterations, modifications, and improvements to the foregoing, all of which are within the scope and the spirit of the present invention. Accordingly, in order to apprehend the scope of the present invention, reference should be made to the appended claims.

What is claimed is:

1. A mounting system for attaching a panel to a surface comprising:
at least one bracket comprising an upper section having a mounting surface and a retaining lip spaced apart to accept an edge of the panel, a riser connected to the upper section, a base connected to the riser and disposed on the surface; and
ballast disposed against the base,
whereby the edge of the panel is locked in place and remains mounted to the surface without mechanical fastening.

2. The mounting system of claim 1, wherein the bracket further comprises a second upper section having a second mounting surface and a second retaining lip spaced apart to accept an edge of a second panel.

3. The mounting system of claim 2, wherein the first and second upper sections are connected to a common base.

4. The mounting system of claim 3, wherein the first and second upper sections are connected to the common base by a single riser.

5. The mounting system of claim 3, wherein the first and second upper sections are connected to the common base by a first riser and a second riser.

6. The mounting system of claim 5, wherein the first and second upper sections are connected to the common base by a first riser of a first height and a second riser of a second height.

7. The mounting system of claim 1, further comprising a grounding clip disposed between the bracket and the panel.

8. The mounting system of claim 1, wherein two brackets are attached to a first edge of a first panel and a third and fourth bracket are attached to a second edge of the same panel.

9. The mounting system of claim 8, wherein the third and fourth brackets are attached to an first edge of a second panel.

10. The mounting system of claim 9, further comprising an air deflector covering a gap between the first panel and the second panel.

11. An array of solar panels mounted to a roof, comprising:
a plurality of brackets each comprising an upper section having a mounting surface and a retaining lip spaced apart to accept an edge of a panel, a riser connected to the upper section, a base connected to the riser and disposed on the surface; and
ballast disposed against the base,
whereby the edge of a panel is locked in place and remains mounted to the surface without mechanical fastening.

12. The array of solar panels of claim 11, wherein each bracket further comprises a second upper section having a second mounting surface and a second retaining lip spaced apart to accept an edge of a second panel, wherein each bracket retains an edge of at least two separate solar panels.

13. The array of solar panels of claim 1, further comprising a separator disposed between an edge of a first panel and an edge of a second panel whereby the clearance between the two panels is substantially eliminated.

14. The array of solar panels of claim 13, wherein each bracket has a first and second mounting surface and a first and second retaining lip.

15. The array of solar panels of claim 13, wherein the first and second mounting surfaces and the first and second retaining lips are disposed on a single riser at a single height above the base.

16. The array of solar panels of claim 13, wherein the first and second mounting surfaces and the first and second retaining lips are disposed, respectively, on a first riser and a second riser at two different heights above the base.

17. The mounting system of claim 12, further comprising an air deflector covering a gap between the first panel and the second panel.

18. The mounting system of claim 11, further comprising a grounding clip disposed between the bracket and the panel.

19. A method of installing an array of solar panels on a surface without using fasteners, comprising the steps of:
placing a pair of brackets on the surface;
placing ballast on the brackets;
providing a solar panel;
sliding an edge of a first panel between a mounting surface and a retaining lip disposed on the brackets;
sliding a second edge of the panel between a second mounting surface and a second retaining lip disposed on a second pair brackets;
moving the first pair of brackets and the second pair of brackets apart so as to lock both the first edge and the second edge in place;
placing ballast on the second pair of brackets;
assembling a second panel according to the steps described above;

20. The method of claim 19, further comprising the step of adding additional panels and of affixing an air deflector to cover a gap between the sets of adjacent panels.

21. The method of claim 19; further comprising the step of placing a separator block or pin to eliminate the clearance between the two panels.
